(19) United States
(12) Patent Application Publication
(10) Pub. No.: US 2025/0225022 A1
(43) Pub. Date: Jul. 10, 2025

(54) METHOD FOR OPERATING SEMICONDUCTOR MANUFACTURING APPARATUS

(71) Applicant: EBARA CORPORATION, Tokyo (JP)

(72) Inventors: Yosuke NAGASAWA, Tokyo (JP); Kazuma IDEGUCHI, Tokyo (JP); Shunsuke KAGAYA, Tokyo (JP); Ryuya KOIZUMI, Tokyo (JP); Tensei SATO, Tokyo (JP)

(21) Appl. No.: 18/988,538

(22) Filed: Dec. 19, 2024

(30) Foreign Application Priority Data
Jan. 5, 2024 (JP) 2024-000817

(51) Int. Cl. G06F 11/07; H01L 21/67

(52) U.S. Cl. CPC G06F 11/0793; G06F 11/0736; H01L 21/67276

(57) ABSTRACT

Objects are to allow an operator to easily grasp cause of abnormality in an apparatus, and to thereby allow quick recovering of the apparatus from the abnormality. A present method comprises steps for: obtaining one or multiple pieces of status information relating to one or multiple processing units in the semiconductor manufacturing apparatus; and making, based on the one or multiple pieces of status information, a judgment as to whether a predetermined operation step in the semiconductor manufacturing apparatus is allowed to be performed; and, in the case that a judgment that disallows performing of the predetermined operation step is made, steps for: performing control to disallow performing of the predetermined operation step; classifying each of the one or multiple pieces of status information into that corresponding to an abnormal state or that corresponding to a normal state and displaying the classified status information; and displaying, on a portable terminal in response to user input that designates status information corresponding to an abnormal state, an AR or MR screen for position guiding to a processing unit corresponding to the designated status information in the one or multiple processing units.

### TECHNICAL FIELD

The present invention relates to a method for operating a semiconductor manufacturing apparatus.

### BACKGROUND ART

For making a semiconductor manufacturing apparatus perform appropriate operation, interlock control has been used widely (for example, refer to Patent Literature 1). Interlock control is a method, that is used when making an apparatus perform certain operation, for controlling the apparatus to prevent it from performing the certain operation if a predetermined condition(s) is not satisfied. Conditions relating to interlock control vary according to kinds of operation; and, in the case that operation expected to be performed by an apparatus is not performed as a result that interlock control is performed, an operator of the apparatus confirms, by using a display screen or the like, matters such as operation that is not performed, although the operation is expected to be performed, as a result that a condition(s) has not been satisfied, and the condition(s) that has not been satisfied.

### CITATION LIST

### Patent Literature

PTL 1: Japanese Patent Application Public Disclosure No. 2012-222099

### SUMMARY OF INVENTION

### Technical Problem

In the case such as that explained above, it is desirable that an operator be able to determine a cause of abnormality in an apparatus and make the apparatus quickly recover from an abnormal state.

### Solution to Problem

(Mode 1) According to Mode 1, a method for operating a semiconductor manufacturing apparatus for making it recover from an abnormal state is provided, and the method comprising steps for: obtaining one or multiple pieces of status information relating to one or multiple processing units in the semiconductor manufacturing apparatus; and making, based on the one or multiple pieces of status information, a judgment as to whether a predetermined operation step in the semiconductor manufacturing apparatus is allowed to be performed, wherein a judgment that disallows performing of the predetermined operation step is to be made if at least one of the one or multiple pieces of status information is that representing an abnormal state; and, in the case that a judgment that disallows performing of the predetermined operation step is made, steps for: performing control to disallow performing of the predetermined operation step; classifying each of the one or multiple pieces of status information into that corresponding to an abnormal state or that corresponding to a normal state and displaying the classified one or multiple pieces of status information; and displaying, on a portable terminal in response to user input that designates status information corresponding to an abnormal state, an AR or MR screen for position guiding to a processing unit corresponding to the designated status information in the one or multiple processing units.

(Mode 2) According to Mode 2, the Mode 2 comprises the method in Mode 1, and the method further comprises a step for displaying, on the AR or MR screen in the portable terminal, an execution button for providing an instruction for performing the predetermined operation step.

(Mode 3) According to Mode 3, the Mode 3 comprises the method in Mode 2, and the execution button is displayed in response to cancellation of an abnormal state in the processing unit which has been selected as the destination of the position guiding.

(Mode 4) According to Mode 4, the Mode 4 comprises the method in Mode 2, and the execution button is invalidated and displayed during the time when the abnormal state of the processing unit, which has been selected as the destination of the position guiding, is continued, and the execution button is validated and displayed in response to cancellation of the abnormal state of the processing unit which has been selected as the destination of the position guiding.

(Mode 5) According to Mode 5, the Mode 5 comprises the method in any one of Modes 2-4, and the one or multiple pieces of status information are obtained from sensors installed in the one or multiple processing units.

(Mode 6) According to Mode 6, the Mode 6 comprises the method in Mode 5, and the method further comprises a step for receiving, by a manipulation terminal in the semiconductor manufacturing apparatus, user input that provides an instruction for performing the predetermined operation step in the semiconductor manufacturing apparatus; wherein, in the step for obtaining, the one or multiple pieces of status information are obtained from the sensors in a processing unit corresponding to the operation step instructed to be performed.

(Mode 7) According to Mode 7, the Mode 7 comprises the method in Mode 6, displaying of the one or multiple pieces of status information is performed in the manipulation terminal, and the user input that designates the status information corresponding to the abnormal state is received by the manipulation terminal.

(Mode 8) According to Mode 8, the Mode 8 comprises the method in Mode 7, and the manipulation terminal and the portable terminal are communicably connected with each other.

(Mode 9) According to Mode 9, the Mode 9 comprises the method in Mode 8, and the method further comprises a step for sending, from the portable terminal to the manipulation terminal, an indication of occurrence of manipulation of the execution button displayed in the portable terminal.

(Mode 10) According to Mode 10, the Mode 10 comprises the method in Mode 9, and the method further comprises a step for performing control to make the predetermined operation step be performed, in response to reception, by the manipulation terminal, of the indication of occurrence of manipulation of the execution button.

### BRIEF DESCRIPTION OF DRAWINGS

FIG. 1 is a perspective view which shows an overall construction of a plating apparatus according to an embodiment of the present invention.

FIG. 2 is a top view which shows an overall construction of a plating apparatus according to an embodiment of the present invention.

FIG. 3 is a configuration diagram of an example system for controlling operation of a semiconductor manufacturing apparatus according to an embodiment of the present invention.

FIG. 4A is a schematic drawing which shows an example tangible construction of a processing unit.

FIG. 4B is a schematic drawing which shows an example tangible construction of a processing unit.

FIG. 5 is a flow chart which shows operation of a system comprising a semiconductor manufacturing apparatus according to an embodiment of the present invention.

FIG. 6 shows an example of a screen which displays status information.

FIG. 7 shows an example of an AR navigation screen displayed in a portable information terminal.

### DESCRIPTION OF EMBODIMENTS

In the following description, embodiments of the present invention will be explained with reference to the figures. In the figures which will be explained below, a reference symbol that is the same as that assigned to one component is assigned to the other component which is the same as or corresponds to the one component, and overlapping explanation of these components will be omitted.

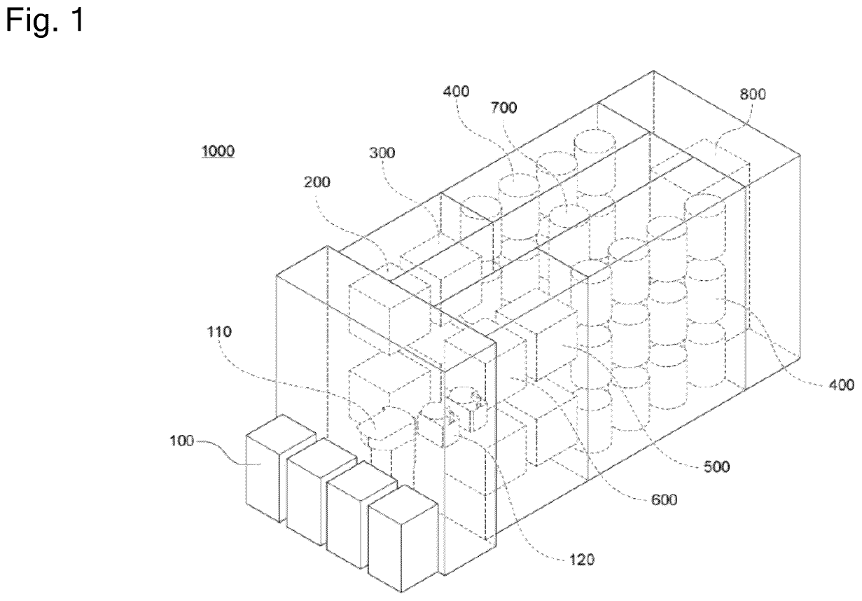

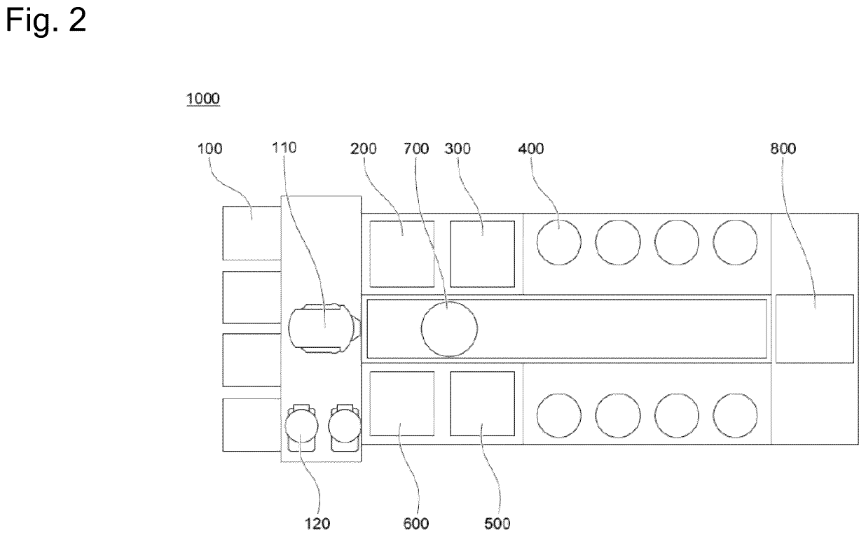

FIG. 1 is a perspective view which shows an overall construction of a plating apparatus 1000 according to an embodiment of the present invention. FIG. 2 is a top view which shows an overall construction of the plating apparatus 1000 according to an embodiment of the present invention. The plating apparatus 1000 is an example of a semiconductor manufacturing apparatus. In the following description, embodiments of the present invention will be explained with reference to the plating apparatus 1000; however, the devices and the methods disclosed in the present specification are applicable to any of semiconductor manufacturing apparatuses, in addition to a plating apparatus. For example, the semiconductor manufacturing apparatuses comprise, in addition to a plating apparatus, any devices which relate to manufacturing of semiconductor products, such as a polishing device for polishing a substrate (a semiconductor substrate, a glass substrate, or the like) or a thin film formed on a substrate (for example, a CMP (Chemical Mechanical Polishing) device and so on), a film forming device for forming a film on a substrate (for example a CVD (Chemical Vapor Deposition) device, a vapor deposition device, and so on), an exposure device for transferring a fine pattern on a thin film on a substrate, an etching device for performing etching for finely processing a substrate or a thin film formed on a substrate, an ion implanting device for implanting ions in a substrate or a thin film formed on a substrate, a dicing device for cutting a substrate to form chips, various kinds of inspection devices (or measurement devices) for inspecting completed semiconductor products or partly-finished products (including substrates), and so on.

As shown in FIGS. 1 and 2, the plating apparatus 1000 comprises a load port 100, a transfer robot 110, an aligner 120, a pre-wet module 200, a pre-soak module 300, a plating module 400, a washing module 500, a spin rinse dryer 600, a transfer device 700, and a control module 800.

The load port 100 is a module for carrying a substrate, which is housed in a cassette such as a FOUP or the like which is not shown in the figure, into the plating apparatus 1000, and carrying a substrate from the plating apparatus 1000 into a cassette. In the present embodiment, four load ports 100 are arranged side by side in a horizontal direction; however, the number of the load ports 100 and arrangement thereof are matters that can be determined optionally. The transfer robot 110 is a robot for conveying a substrate, and is constructed to deliver a substrate between the load port 100, the aligner 120, and the transfer device 700. Regarding the transfer robot 110 and the transfer device 700, when a substrate is delivered between the transfer robot 110 and the transfer device 700, delivering of the substrate can be performed via a temporary holding table which is not shown in the figure.

The aligner 120 is a module for aligning, in a predetermined direction, a position of an orientation flat, a notch, or the like of a substrate. In the present embodiment, two aligners 120 are arranged side by side in a horizontal direction; however, the number of the aligners 120 and arrangement thereof are matters that can be determined optionally. The pre-wet module 200 makes a to-be-plated surface of a substrate, which is in a state before application of a plating process, wet by applying a treatment liquid such as pure water, degassed water, or the like thereto, to thereby replace air existing in the inside of a pattern formed on the surface of the substrate by the treatment liquid. The pre-wet module 200 is constructed to perform a pre-wet process that facilitates supplying of a plating liquid to the inside of the pattern during a plating process, by replacing the treatment liquid in the inside of the pattern by the plating liquid. In the present embodiment, two pre-wet modules 200 are arranged side by side in a vertical direction; however, the number of the pre-wet modules 200 and arrangement thereof are matters that can be determined optionally.

The pre-soak module 300 is constructed to perform, for example, a pre-soak process for removing, by performing an etching process using a treatment liquid such as sulfuric acid, hydrochloric acid, or the like, an oxide film which has large electric resistance and exists on a surface of a seed layer or the like formed on a to-be-plated surface of a substrate which is in a state before application of a plating process, and washing or activating a surface of a ground to which a plating process is to be applied. In the present embodiment, two pre-soak modules 300 are arranged side by side in a vertical direction; however, the number of the pre-soak modules 300 and arrangement thereof are matters that can be determined optionally. The plating modules 400 applies a plating process to a substrate. In the present embodiment, two sets of plating modules 400 are included; wherein each set includes 12 plating modules 400 which are arranged in such a manner that three plating modules 400 are arranged side by side in a vertical direction and four plating modules 400 are arranged side by side in a horizontal direction, so that a total of 24 plating modules 400 are installed; however, the number of the plating modules 400 and arrangement thereof are matters that can be determined optionally.

The washing module 500 is constructed to perform a washing process applied to a substrate for removing a plating liquid and so on remaining on the substrate which is in a state after completion of the plating process. In the present embodiment, two washing modules 500 are arranged side by side in a vertical direction; however, the number of the washing modules 500 and arrangement thereof are matters that can be determined optionally. The spin rinse dryer 600 is a module for drying a substrate, which is in a state after completion of the washing process, by rotating it at high speed. In the present embodiment, two spin rinse dryers are arranged side by side in a vertical direction; however, the number of the spin rinse dryers and arrangement thereof are matters that can be determined optionally. The transfer device 700 is a device for conveying a substrate between multiple modules in the plating apparatus 1000. The control module 800 is constructed to control multiple modules in the plating apparatus 1000, and may be constructed by using, for example, a general-purpose computer or a special-purpose computer comprising an input/output interface for communication with an operator.

An example of a series of processes of plating by the plating apparatus 1000 will be explained. First, a substrate housed in a cassette is carried in the load port 100. Next, the transfer robot 110 takes the substrate out of the cassette in the load port 100, and conveys the substrate to the aligner 120. The aligner 120 aligns, in a predetermined direction, a position of an orientation flat, a notch, or the like of the substrate. The transfer robot 110 conveys the substrate, which has been aligned in terms of the direction by the aligner 120, to the transfer device 700.

The transfer device 700 conveys the substrate received from the transfer robot 110 to the pre-wet module 200. The pre-wet module 200 applies a pre-wet process to the substrate. The transfer device 700 conveys the substrate, with respect to which the applied pre-wet process has been completed, to the pre-soak module 300. The pre-soak module 300 applies a pre-soak process to the substrate. The transfer device 700 conveys the substrate, with respect to which the applied pre-soak process has been completed, to the plating module 400. The plating module 400 apples a plating process to the substrate.

The transfer device 700 conveys the substrate, with respect to which the applied plating process has been completed, to the washing module 500. The washing module 500 applies a washing process to the substrate. The transfer device 700 conveys the substrate, with respect to which the applied washing process has been completed, to the spin rinse dryer 600. The spin rinse dryer 600 applies a drying process to the substrate. The transfer device 700 conveys the substrate, with respect to which the applied drying process has been completed, to the transfer robot 110. The transfer robot 110 conveys the substrate received from the transfer device 700 to the cassette in the load port 100. Finally, the cassette, in which the substrate has been housed, is carried out of the load port 100.

In this regard, the construction of the plating apparatus 1000 explained in relation to FIGS. 1 and 2 is a mere example, and the construction of the plating apparatus 1000 is not limited to any of the constructions shown in FIGS. 1 and 2.

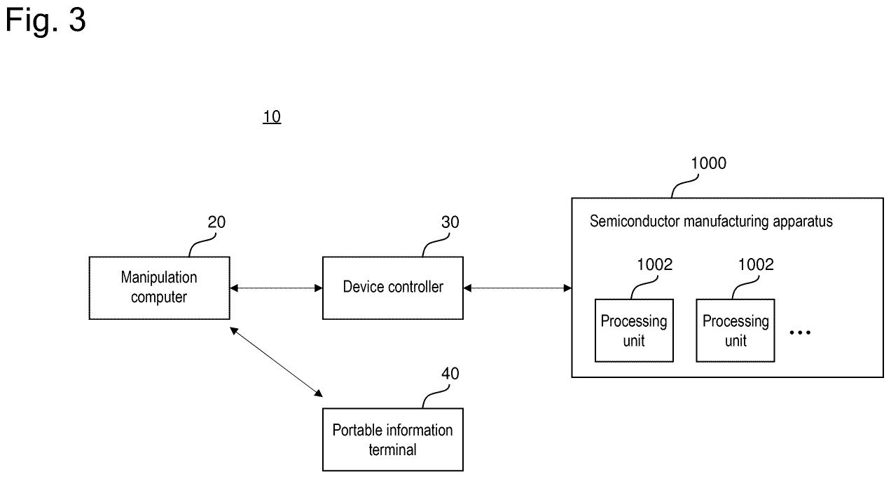

FIG. 3 is a configuration diagram of an example system 10 for controlling operation of the semiconductor manufacturing apparatus (for example, a plating apparatus) 1000 according to an embodiment of the present invention. The system 10 comprises the semiconductor manufacturing apparatus 1000, a computer 20 for manipulation, a device controller 30, and a portable information terminal 40. In the system 10, the semiconductor manufacturing apparatus 1000, the manipulation computer 20, the device controller 30, and the portable information terminal 40 are communicably connected with one another via a communication path such as a local area network (LAN) or the like.

The manipulation computer 20 is a computer which is used by an operator of the system 10 when the operator performs manipulation for the semiconductor manufacturing apparatus 1000. For example, the manipulation computer 20 may be installed in an operation room in a place distant from a place where the semiconductor manufacturing apparatus 1000 has been installed, and an operator may perform manipulation for the semiconductor manufacturing apparatus 1000 by using the manipulation computer 20 in the operation room. The manipulation computer 20 may be realized by using a general purpose computer comprising a processor and a memory, and constructed in such a manner that the processor reads a predetermined program stored in the memory and executes the program to thereby perform predetermined operation. Specifically, the manipulation computer 20 receives, from an operator of the system 10, an instruction for operation of the semiconductor manufacturing apparatus 1000 (for example, receives data input via a user interface), and supplies the operation instruction to the device controller 30. Further, the manipulation computer 20 receives, from the device controller 30, status information relating to states of operation of respective parts of the semiconductor manufacturing apparatus 1000, and informs an operator of the status information (for example, displays it on a screen of a display).

The device controller 30 is a computer constructed to perform control of operation of the semiconductor manufacturing apparatus 1000. The device controller 30 may be any computer comprising a processor and a memory. For example, a PLC (Programmable Logic Controller) may preferably be used as the device controller 30; however, the device controller 30 may be a kind of computer different from a PLC. The device controller 30 controls the semiconductor manufacturing apparatus 1000 by converting an instruction for operation of the semiconductor manufacturing apparatus 1000, that has been sent from the manipulation controller 20, to an instruction having a form that can be understood by the semiconductor manufacturing apparatus 1000 (respective parts of the semiconductor manufacturing apparatus 1000), and supplying the converted instruction to the semiconductor manufacturing apparatus 1000. Further, the device controller 30 collects, from the respective parts of the semiconductor manufacturing apparatus 1000, status information relating to states of operation of the respective parts, and supplies the status information to the manipulation computer 20. In this regard, the control module 800 shown in each of FIGS. 1 and 2 may be that corresponds to the device controller 30 in FIG. 3.

The portable information terminal 40 is an auxiliary computer terminal which is used by an operator of the system 10 for performing manipulation for the semiconductor manufacturing apparatus 1000. For example, the portable information terminal 40 may be any kind of information terminal, such as a tablet terminal, a notebook computer, a smartphone, or the like, which can be carried and used by an operator. The portable information terminal 40 is constructed to have a function that allows communication with the manipulation computer 20, for example, via a wireless LAN; and communicate, with the manipulation computer 20 from a place other than a place where the manipulation computer 20 has been installed (for example, a place near the semiconductor manufacturing apparatus 1000), data that is required when manipulation for the semiconductor manufacturing apparatus 1000 is performed by an operator. As shown in FIG. 3, the semiconductor manufacturing apparatus 1000 comprises one or multiple processing units 1002. For example, in the case that the semiconductor manufacturing apparatus 1000 is the plating apparatus explained in relation to FIGS. 1 and 2, each processing unit 1002 in FIG. 3 may be any one of the load port 100, the transfer robot 110, the aligner 120, the pre-wet module 200, the pre-soak module 300, the plating module 400, the washing module 500, the spin rinse dryer 600, and the transfer device 700 shown in FIGS. 1 and 2. In a different construction, each processing unit 1002 may be that representing a component/subcomponent of each of the above parts (100, 110, 120, 200, 300, 400, 500, 600, and 700) (for example, one of components which constitute the plating module 400). Further, although it is needless to state, in the case that the semiconductor manufacturing apparatus 1000 is a semiconductor manufacturing apparatus other than a plating apparatus, each processing unit 1002 in FIG. 3 may be that corresponding to one of components/subcomponents which constitute the semiconductor manufacturing apparatus and are classified according to the type of the semiconductor manufacturing apparatus.

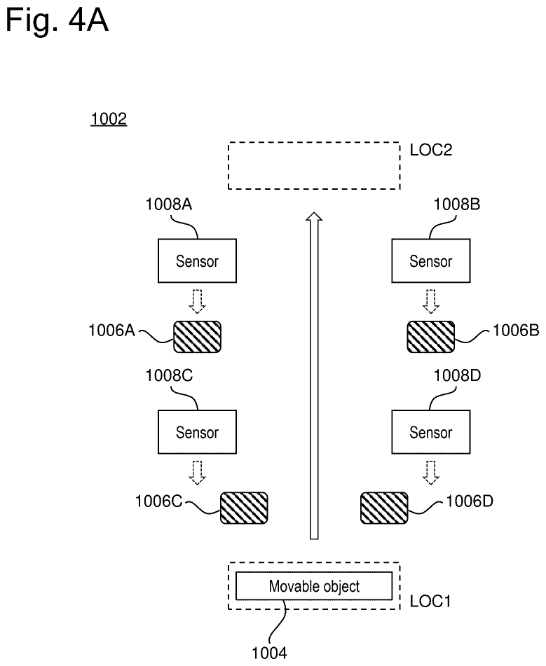

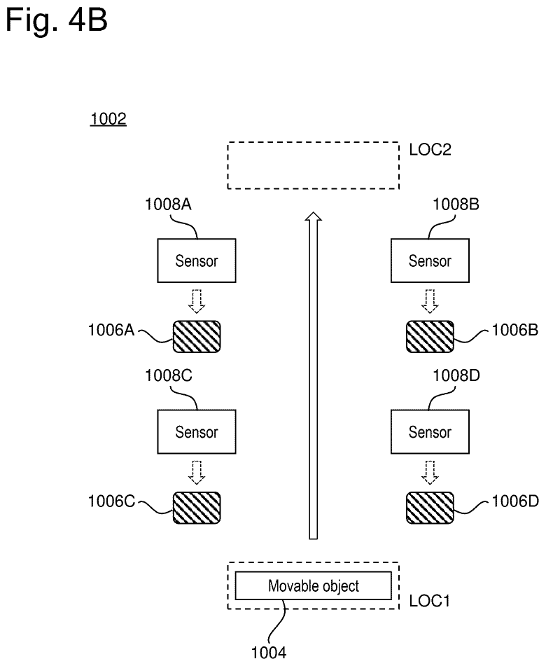

Each of FIG. 4A and FIG. 4B is a schematic drawing that shows, for better understanding of the following explanation, an example tangible construction of a processing unit 1002. In each of FIG. 4A and FIG. 4B, the processing unit 1002 comprises a movable object 1004, structures 1006A-1006D, and sensors 1008A-1008D. For example, the movable object 1004 may be a substrate which is an object of processing in the processing unit 1002, or an aggregate comprising a substrate and a substrate holder holding the substrate. The movable object 1004 can move between a first position LOC1 and a second position LOC2 by using a transfer mechanism which is not shown in the figures. For example, the first position LOC1 may be a position in the processing unit 1002 where a substrate is processed (for example, a plating process is performed), and the second position LOC2 may be a waiting position where a substrate that has not yet been processed stays before it is moved to the first position LOC1, or a substrate moved from the first position LOC1 stays after completion of a process applied thereto. Each of the structures 1006A-1006D may be a cover of a plating tank which opens when it is used, a clamp for fixing a substrate in a tank, or the like, for example. Each of the structures 1006A-1006D is able to move between an interfering position and a retreat position by using a transfer mechanism which is not shown in the figures. Each of the interfering positions is a position that functions in such a manner that movement of the movable object 1004 between the first position LOC1 and the second position LOC2 is blocked when at least one of the structures 1006A-1006D stays in a corresponding interfering position in the interfering positions. The retreat positions are positions that do not interfere with movement of the movable object 1004 between the first position LOC1 and the second position LOC2. For example, in the arrangement example in FIG. 4A, the structures 1006A and 1006B stay in the retreat positions, and the structures 1006C and 1006D stay in the interfering positions. On the other hand, in the arrangement example in FIG. 4B, all structures 1006A-1006D stay in the retreat positions. The sensors 1008A-1008D are sensors for detecting whether the corresponding structures 1006A-1006D stay in the interfering positions or the retreat positions, respectively.

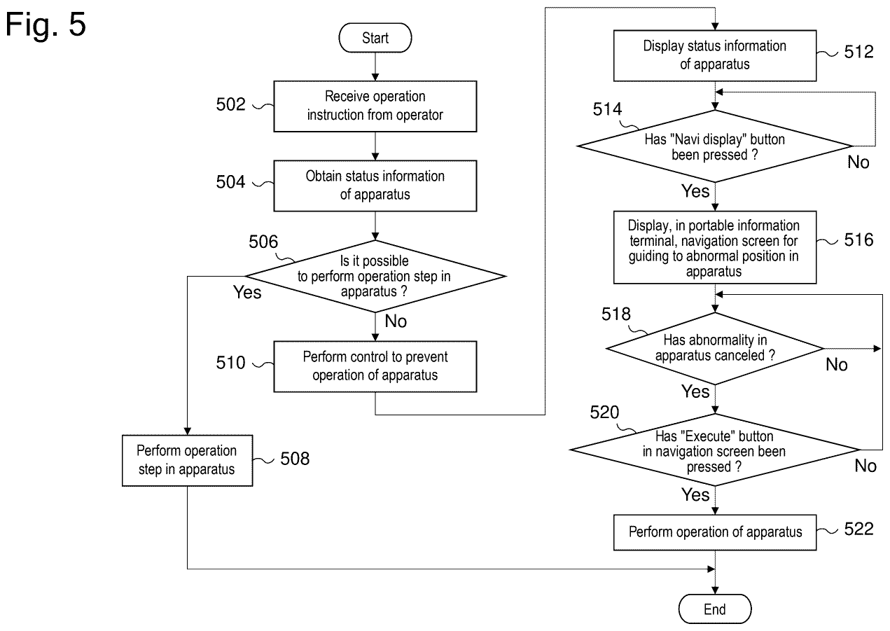

FIG. 5 is a flow chart which shows operation of the system 10 comprising the semiconductor manufacturing apparatus 1000, according to an embodiment of the present invention. In the system 10, the manipulation computer 20, the device controller 30, and the portable information terminal 40 cooperate with one another to perform processes in respective steps in the flow chart in FIG. 5, to thereby perform interlock control applied when the semiconductor manufacturing apparatus 1000 is in an abnormal state, and, in addition, make it possible to recover in an appropriate manner from the abnormal state.

In step 502, the manipulation computer 20 receives, from an operator of the system 10, an operation instruction for the semiconductor manufacturing apparatus 1000. For example, the operator of the system 10 may input, via a user interface of the manipulation computer 20, a desired operation instruction for the semiconductor manufacturing apparatus 1000. For example, the operation instruction may be an instruction for moving the movable object 1004 in the processing unit 1002 in the semiconductor manufacturing apparatus 1000 from the first position LOC1 to the second position LOC2 (refer to FIGS. 4A and 4B). The operation instruction is sent from the manipulation computer 20 to the device controller 30.

Next, in step 504, the device controller 30 obtains status information of the semiconductor manufacturing apparatus 1000. Specifically, the device controller 30 obtains, from one processing unit or each one of multiple processing units in the processing units 1002 in the semiconductor manufacturing apparatus 1000, a single piece or multiple pieces of status information. For example, the single piece or the multiple pieces of status information may be an operation state or operation states of the processing unit 1002 detected by a single sensor or multiple sensors in the sensors 1008A-1008D (refer to FIGS. 4A and 4B) installed in the processing unit 1002. For example, in the arrangement example in FIG. 4A, the device controller 30 obtains, from the sensors 1008A and 1008B, pieces of status information (for example, “ON”) representing states that the structures 1006A and 1006B stay in the retreat positions, respectively, and obtains, from the sensors 1008C and 1008D, pieces of status information (for example, “OFF”) representing states that the structures 1006C and 1006D stay in the interfering positions, respectively.

Next, in step 506, based on the status information obtained in step 504, the device controller 30 makes a judgment as to whether it is possible to perform an operation step in the semiconductor manufacturing apparatus 1000 corresponding to the operation instruction received from the operator in step 502. For example, in the case that the above example is continuously used herein, the device controller 30 makes, based on the status information (for example, status information obtained from the sensors 1008A-1008D), a judgment as to whether it is possible to perform an operation step for moving the movable object 1004 in the processing unit 1002 from the first position LOC1 to the second position LOC2.

More specifically, for example, in the case that the structures 1006A-1006D in the processing unit 1002 have been arranged in the manner shown in FIG. 4A, each of the structures 1006C and 1006D is in the state (abnormal state) that it will be in contact with the movable object 1004 if the movable object 1004 is moved from the first position LOC1. Status information “OFF” corresponding to the above abnormal state is obtained from each of the sensors 1008C and 1008D; and the device controller 30 makes a judgment that prevents performing of the operation step for moving the movable object 1004 from the first position LOC1 to the second position LOC2, for preventing damage to the movable object 1004 (for example, a substrate) and the structures 1006C and 1006D. The device controller 30 may make a judgment that prevents performing of the operation step for moving the movable object 1004 from the first position LOC1 to the second position LOC2, in the case that at least one piece of the status information is that representing “OFF.”

On the other hand, in the case that the structures 1006A-1006D in the processing unit 1002 have been arranged in the manner shown in FIG. 4B, the movable object 1004 that is to be moved from the first position LOC1 will not be in contact with any of the structures 1006A-1006D (a normal state). In this case, status information “ON” corresponding to the normal state is obtained from each of the sensors 1008A-1008D; and the device controller 30 judges that it is possible to perform the operation step for moving the movable object 1004 from the first position LOC1 to the second position LOC2.

If it is judged in above step 506 that it is possible to perform the operation step in the semiconductor manufacturing apparatus 1000, the process proceeds to step 508. In step 508, the device controller 30 sends, to the semiconductor manufacturing apparatus 1000, an instruction that instructs the semiconductor manufacturing apparatus 1000 to perform the operation step (for example, moving the movable object 1004 from the first position LOC1 to the second position LOC2). According thereto, the semiconductor manufacturing apparatus 1000 performs the operation instructed by the operator in step 502.

If it is judged in above step 506 that performing of the operation step in the semiconductor manufacturing apparatus 1000 is to be prevented (the operation step cannot be performed), the process proceeds to step 510. In step 510, the device controller 30 controls the semiconductor manufacturing apparatus 1000 to prevent it from performing the operation step (for example, moving the movable object 1004 from the first position LOC1 to the second position LOC2). Specifically, the instruction for instructing the semiconductor manufacturing apparatus 1000 to perform the operation step is not sent to the semiconductor manufacturing apparatus 1000. Accordingly, the operation instructed by the operator in step 502 is not performed in the semiconductor manufacturing apparatus 1000. In this manner, by adopting the processes in steps 506-510, interlock control, that makes the semiconductor manufacturing apparatus 1000 perform an operation step only when a predetermined condition is satisfied (for example, the status information obtained from every one of the sensors 1008A-1008D is “ON”), is realized.

In step 512 that follows above step 510 (i.e., in the case that the operation step in the semiconductor manufacturing apparatus 1000 is not performed), the device controller 30 sends the status information of the semiconductor manufacturing apparatus 1000 obtained in step 504 to the manipulation computer 20, and the manipulation computer 20 receives the status information and informs the operator of the status information. Specifically, the manipulation computer 20 classifies a single piece of or each one of multiple pieces of status information into one kind of status information corresponding to a normal state or the other kind of status information corresponding to an abnormal state, and displays the classified status information in a screen of a display.

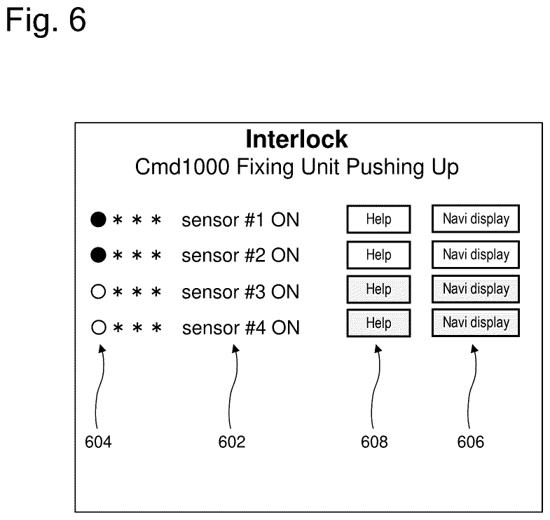

FIG. 6 shows an example of a screen which displays status information. In the example in FIG. 6, the display screen comprises a list 602 of all sensors (for example, sensors 1008A-1008D) in a processing unit 1002 in which an abnormal event(s) has been occurred, and discrimination indicators 604, wherein each discrimination indicator is that showing whether the status information from a sensor is abnormal or normal. For example, the discrimination indicator 604 may be represented by a circle, wherein an abnormal state may be represented by a circle having a first color or first brightness, and a normal state may be represented by a circle having a second color that is different from the first color or second brightness that is different from the first brightness. In the example in FIG. 6, it is shown that the status information from each of the sensors 1008C and 1008D is in an abnormal state, and the status information from each of the sensors 1008A and 1008B is in a normal state. The operator of the system 10 is able to easily grasp, by observing a display screen such as that in the display in the manipulation computer 20, a processing unit(s) 1002 which is included in the semiconductor manufacturing apparatus 1000 and in which an abnormal event(s) has been occurred, and the type(s) of the abnormal event(s) that has been occurred therein.

In the example in FIG. 6, the display screen further comprises “Navi display” buttons 606 which correspond to the sensors in the list, respectively. Each of the “Navi display” buttons 606 is a button used for showing display for position guiding that guides, by using the portable information terminal 40, the operator of the system 10 to a position where an abnormal event has been occurred in the semiconductor manufacturing apparatus 1000. The displays screen further comprises “Help” buttons 608, wherein each of the “Help” buttons 608 is used for displaying, on the display in the manipulation computer 20, an explanation (an operation manual or the like) relating to a sensor which has outputted information representing an abnormal event, and/or a structure (for example, one of the structures 1006A-1006D) corresponding to the sensor.

In step 514 that follows step 512, the manipulation computer 20 makes a judgment as to whether user input, that designates status information corresponding to an abnormal state, has been performed. The judgment may be based on whether a “Navi display” button 606 in the display screen in the manipulation computer 20 has been pressed. For example, in the case that one of the discrimination indicators 604 in the example display screen in FIG. 6 shows an abnormal state, the operator of the system 10 is required to go to a position where an abnormal event has occurred in the semiconductor manufacturing apparatus 1000 to check an actual state of a device, adjust or maintain an abnormal part in the position, and so on. In such a case, the operator pushes a “Navi display” button 606 corresponding to the abnormal state shown in the display screen.

Next, in step 516, i.e., after the above user input operation (for example, manipulation of the “Navi display” button 606) is performed, the manipulation computer 20 sends, to the portable information terminal 40, identification information of the processing unit 1002 (and/or the sensor and the structure relating to the abnormal state in the processing unit 1002) relating to the status information that is in the abnormal state and has been designated by the user input; and, based on the identification information, the portable information terminal 40 displays, in a display in the portable information terminal 40, a navigation screen for guiding the operator to a place of installation of the processing unit 1002 (or a place of installation of the sensor or the structure in the processing unit 1002) corresponding to the position where the abnormal event has occurred in the semiconductor manufacturing apparatus 1000. The navigation screen may be an AR (augmented reality) screen or an MR (mixed reality) screen.

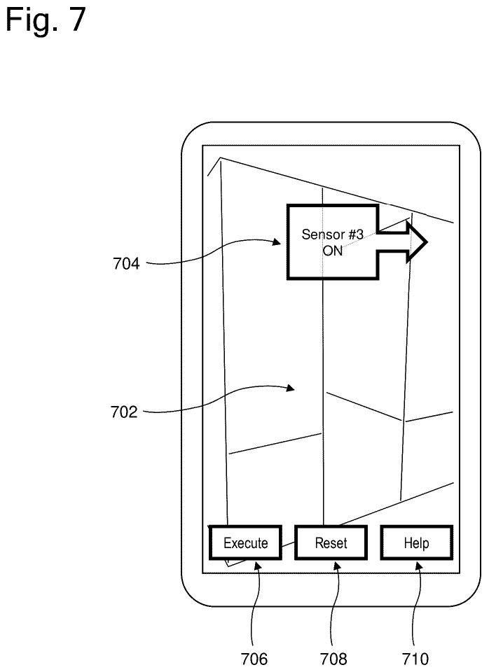

FIG. 7 shows an example of an AR navigation screen displayed in the portable information terminal 40. As shown in FIG. 7, the AR navigation screen comprises a background image 702 and a guide display 704. The background image 702 is a live image taken by a camera installed in the portable information terminal 40. The guide display 704 shows, for example, by displaying an arrow image, a direction toward a part in the semiconductor manufacturing apparatus 1000 where an abnormal event has occurred and is the destination of position guiding. The portable information terminal 40 is able to detect, by using a well-known existing technique, the position of the portable information terminal 40 and the direction toward that the portable information terminal 40 is oriented at present; calculate, by using the result of above detection, relative positions of the portable information terminal 40 and the position where the abnormal event has occurred in the semiconductor manufacturing apparatus 1000, and a relative direction; and, according to the result of above calculation, update the guide display 704 whenever necessary and display it. The operator of the system 10 is able to quickly identify the position where the abnormal event has occurred in the semiconductor manufacturing apparatus 1000, by viewing the guide display 704 on the background image 702 corresponding to the real world.

The AR navigation screen further comprises an “Execute” button 706 and a “Reset” button 708. The “Execute” button 706 is a button for manipulating the semiconductor manufacturing apparatus 1000 from the portable information terminal 40 to make the semiconductor manufacturing apparatus 1000 perform an operation step that was not performed in the semiconductor manufacturing apparatus 1000 due to the interlock control in step 510. The “Reset” button 708 is a button for resetting (or restarting) the whole semiconductor manufacturing apparatus 1000 or a processing unit 1002 in which an abnormal event has occurred. The AR navigation screen may further comprise a “Help” button 710 similar to the “Help” buttons 608 in the display screen in FIG. 6, and an operation manual or the like corresponding to an abnormal part (a sensor or the like) may be allowed to be displayed on the AR navigation screen.

After referring to the navigation screen in the portable information terminal 40 and thereby arriving at the position in the semiconductor manufacturing apparatus 1000 where the abnormal event has occurred (i.e., after identifying the position where the abnormal event has occurred), the operator of the system 10 checks details of the abnormal event, and performs adjustment/maintenance of a device (for example, the sensors 1008A-1008D, the structures 1006A-1006D and so on) relating to the abnormal event.

In step 518, the manipulation computer 20 obtains the newest status information of the semiconductor manufacturing apparatus 1000 via the device controller 30, and makes a judgment as to whether all pieces of status information that have been displayed as those representing abnormal states in the status information displaying screen (refer to FIG. 6) have been corrected to those representing normal states. For example, in the examples in FIGS. 4A and 6 explained above, the status information from each of the sensor 1008C and the sensor 1008D is that representing an abnormal state. The manipulation computer 20 makes a judgment as to whether the status information from each of the sensor 1008C and the sensor 1008D has been changed from that representing an abnormal state to that representing a normal state. The state that the status information from every one of the sensors 1008A-1008D has become that representing a normal state, as a result that the status information from each of the sensor 1008C and the sensor 1008D has been changed from that representing an abnormal state to that representing a normal state, means that it has become possible to perform the operation step for moving the movable object 1004 from the first position LOC1 to the second position LOC2.

When all pieces of the status information have been confirmed as those representing normal states in step 518, the manipulation computer 20 may notify the portable information terminal 40 of information representing the above confirmation result; and, in response to reception of the above information, the portable information terminal 40 may display the “Execute” button 706 on the AR navigation screen (that is, the “Execute” button 706 is not displayed on the AR navigation screen before reception of the above information, and the “Execute” button 706 is displayed on the AR navigation screen only after reception of the above information). In a different construction, the “Execute” button 706 in an invalidated state is displayed on the AR navigation screen before reception of the above information, and the “Execute” button 706 is validated after reception of the above information. By the above construction, it becomes possible to prevent the semiconductor manufacturing apparatus 1000 from erroneously performing an operation step, when the “Execute” button 706 in the portable information terminal 40 is manipulated in the state that an abnormal state has not yet been canceled.

It should be reminded that the system 10 may comprise multiple portable information terminals 40, and multiple operators may be allowed to carry the multiple portable information terminals 40 and perform their tasks, respectively. In the above case, it is possible to apply restriction such that pressing of the “Execute” button 706 is allowed only in a single portable information terminal 40 in the multiple portable information terminals 40. For example, a “Manipulation allowed” button is displayed in addition to the “Execute” button 706 in the AR navigation screen in each of the portable information terminals 40 (at this point, pressing of the “Execute” button 706 is not allowed), and, when a “Manipulation allowed” button is pressed in one portable information terminal 40 in the portable information terminals 40, pressing of the “Execute” button 706 is allowed in the one portable information terminal 40 (pressing of the “Execute” button 706 is still not allowed in other portable information terminals 40).

If it is judged in step 518 that all pieces of status information are those representing normal states, the process proceeds to step 520, and the portable information terminal 40 makes a judgment as to whether the “Execute” button 706 in the AR navigation screen has been pressed. If the “Execute” button 706 is pressed, the portable information terminal 40 notifies the manipulation computer 20 of information relating to the above button pressing action. Next, in step 522, the manipulation computer 20 instructs, in response to reception of the above information, the device controller 30 to perform an operation step in the semiconductor manufacturing apparatus 1000 (for example, operation for moving the movable object 1004 from the first position LOC1 to the second position LOC2) that has not been performed due to the interlock control. As a result of the above process, the above operation steps is performed in the semiconductor manufacturing apparatus 1000. As explained above, after cancellation of an abnormal state, an operation step in the semiconductor manufacturing apparatus 1000 can be started by performing manipulation by using the portable information terminal 40 (for example, without necessity to return to the place of installation of the manipulation computer 20).

In the above description, embodiments of the present invention have been explained based on some examples; and, in this regard, the above embodiments of the present invention are those used for facilitating understanding of the present invention, and are not those used for limiting the present invention. It is obvious that the present invention can be changed or modified without departing from the scope of the gist thereof, and that the present invention includes equivalents thereof. Further, it is possible to arbitrarily combine components or omit a component(s) disclosed in the claims and the specification, within the scope that at least part of the above-stated problems can be solved or within the scope that at least part of advantageous effect can be obtained.

### REFERENCE SIGNS LIST

100 Load port
110 Transfer robot
120 Aligner
200 Pre-wet module
300 Pre-soak module
400 Plating module
500 Washing module
600 Spin rinse dryer
700 Transfer device
800 Control module
10 System
20 Manipulation computer
30 Device controller
40 Portable information terminal
1000 Plating apparatus
1002 Processing unit
1004 Movable object
1006 Structure
1008 Sensor

What is claimed is:

1. A method for operating a semiconductor manufacturing apparatus to recover from an abnormal state, comprising:
obtaining one or multiple pieces of status information relating to one or multiple processing units in the semiconductor manufacturing apparatus;
judging, based on the one or multiple pieces of status information, whether a predetermined operation step in the semiconductor manufacturing apparatus is allowed to be performed, wherein it is judged to disallow performing of the predetermined operation step if at least one of the one or multiple pieces of status information represents an abnormal state; and,
in the case that it is judged to disallow performing of the predetermined operation step, controlling to disallow performing of the predetermined operation step;
classifying each of the one or multiple pieces of status information into that corresponding to an abnormal state and that corresponding to a normal state to display the classified one or multiple pieces of status information; and
in response to user input that designates status information corresponding to an abnormal state, displaying on a portable terminal an AR or MR screen for position guiding to a processing unit corresponding to the designated status information in the one or multiple processing units.

2. The method as recited in claim 1 further comprising displaying, on the AR or MR screen in the portable terminal, an execution button for providing an instruction for performing the predetermined operation step.

3. The method as recited in claim 2, wherein the execution button is displayed in response to cancellation of an abnormal state in the processing unit which has been selected as the destination of the position guiding.

4. The method as recited in claim 2, wherein the execution button is invalidated and displayed during the time when the abnormal state of the processing unit, which has been selected as the destination of the position guiding, is continued, and the execution button is validated and displayed in response to cancellation of the abnormal state of the processing unit which has been selected as the destination of the position guiding.

5. The method as recited in claim 2, wherein the one or multiple pieces of status information are obtained from sensors installed in the one or multiple processing units.

6. The method as recited in claim 5 further comprising,
receiving, by a manipulation terminal in the semiconductor manufacturing apparatus, user input that provides an instruction for performing the predetermined operation step in the semiconductor manufacturing apparatus;
wherein, in the step of obtaining, the one or multiple pieces of status information are obtained from the sensors in a processing unit corresponding to the operation step instructed to be performed.

7. The method as recited in claim 6, wherein
displaying of the one or multiple pieces of status information is performed in the manipulation terminal, and
the user input that designates the status information corresponding to the abnormal state is received by the manipulation terminal.

8. The method as recited in claim 7, wherein the manipulation terminal and the portable terminal are communicably connected with each other.

9. The method as recited in claim 8 further comprising sending, from the portable terminal to the manipulation terminal, an indication of occurrence of manipulation of the execution button displayed in the portable terminal.

10. The method as recited in claim 9 further comprising controlling to perform the predetermined operation step, in response to receiving, by the manipulation terminal, the indication of occurrence of manipulation of the execution button.
